(19) United States
(12) Patent Application Publication
(10) Pub. No.: US 2011/0104395 A1
(43) Pub. Date: May 5, 2011

(54) FILM DEPOSITION APPARATUS, FILM DEPOSITION METHOD, AND STORAGE MEDIUM

(75) Inventors: Takeshi KUMAGAI, Iwate (JP); Yasushi Takeuchi, Iwate (JP); Hitoshi Kato, Iwate (JP)

(73) Assignee: TOKYO ELECTRON LIMITED, Tokyo (JP)

(21) Appl. No.: 12/912,910

(22) Filed: Oct. 27, 2010

(30) Foreign Application Priority Data
Nov. 2, 2009 (JP) 2009-252375

(51) Int. Cl. C23C 16/46; C23C 16/44; B05D 3/00

(52) U.S. Cl. 427/554; 118/725

(57) ABSTRACT

In a film deposition apparatus where bis (tertiary-butylamino) silane (BTBAS) gas is adsorbed on a wafer and then O₃ gas is adsorbed on the wafer so that the BTBAS gas is oxidized by the O₃ gas thereby depositing a silicon oxide film by rotating a turntable on which the wafer is placed, a laser beam irradiation portion is provided that is capable of irradiating a laser beam to an area spanning from one edge to another edge of a substrate receiving area of the turntable along a direction from an inner side to an outer side of the table.

### CROSS-REFERENCE TO RELATED APPLICATION

This application claims the benefit of priority of Japanese Patent Application No. 2009-252375, filed on Nov. 2, 2009, with the Japanese Patent Office, the entire contents of which are hereby incorporated by reference.

### BACKGROUND OF THE INVENTION

1. Field of the Invention

This invention relates to a film deposition process technology for performing a film deposition process where a substrate on a rotation table and a reaction gas supplying portion are rotated with respect to each other, so that at least two reaction gases are alternately supplied to the substrate.

2. Description of the Related Art

There has been known a film deposition apparatus where a film deposition process is performed while plural substrates such as semiconductor wafers placed on a turntable are rotated in relation to a reaction gas supplying portion, as an apparatus for performing a film deposition method that deposits a film on the substrates employing the reaction gas under a vacuum environment. Patent Documents listed below describe film deposition apparatuses of so-called mini-batch type that are configured so that plural kinds of reaction gases are supplied from reaction gas supplying portions to the substrates and the reaction gases are separated by, for example, providing partition members between areas where the corresponding gases are supplied, or ejecting inert gas to create a gas curtain between the areas, thereby reducing intermixture of the reaction gases. By using such an apparatus, an Atomic Layer Film deposition (ALD) or Molecular Layer Film deposition (MLD) where a first reaction gas and a second reaction gas are alternately supplied to the substrates is performed.

In such a film deposition apparatus, when the plural substrates placed on the turntable are heated, all the substrates are heated at a time by entirely heating the turntable, for example. Because of this, a relatively large and high power heater is required, which leads to increased energy consumption in the film deposition apparatus. In addition, when a large heater is used, the film deposition apparatus is also entirely heated so that high temperature environment is created in a vacuum chamber of the film deposition apparatus by irradiation heat from the heater, which requires a cooling mechanism that cools the vacuum chamber or the entire film deposition apparatus. Therefore, the film deposition apparatus tends to be very complicated.

When the ALD method is performed to deposit a thin film, impurities such as organic materials included in the reaction gases or moisture may be incorporated into the thin film if a deposition temperature is lower. In order to make such impurities be degassed from the thin film to obtain dense and low-impurity thin film, it is required to perform a post-process such as an anneal (thermal) process with respect to the substrates at temperatures of several hundreds degrees Celsius. Such a post-process increases the number of fabrication processes, thereby increasing production costs.

Although Patent Documents 1 and 4 describe a method of heating wafers by using a laser beam, for example, specific configurations that enable such heating are not provided.
Patent Document 1: U.S. Pat. No. 7,153,542 (FIGS. 8(a) and 8(b))
Patent Document 2: Japanese Patent Publication No. 3,144,664 (FIGS. 1 and 2, claim 1)
Patent Document 3: U.S. Pat. No. 6,634,314
Patent Document 4: Japanese Patent Application Laid-Open Publication No. 2006-229075

The present invention has been made in view of the above and provides a film deposition apparatus and a film deposition method that are capable of reducing energy consumption for producing reaction products when performing a deposition process by alternately supplying at least two reaction gases to the substrate, and a storing medium that stores a computer program for causing the film deposition apparatus to perform the film deposition method.

### SUMMARY OF THE INVENTION

According to a first aspect of the present invention, there is provided a film deposition apparatus for depositing a film on a substrate by performing a cycle of alternately supplying at least two kinds of reaction gases that react with each other to the substrate to produce a layer of a reaction product in a vacuum chamber. The film deposition apparatus includes a table that is provided in the vacuum chamber and has a substrate receiving area in which the substrate is placed; a first reaction gas supplying portion that supplies a first reaction gas to the substrate on the table; a second reaction gas supplying portion that supplies a second reaction gas to the substrate on the table; a laser beam irradiation portion that is provided opposing the substrate receiving area so that the laser beam irradiation portion is capable of irradiating a laser beam to an area spanning from one edge to another edge of the substrate receiving area along a direction from an inner side to an outer side of the table; a rotation mechanism that enables a relative rotation of the table and a combination of the first reaction gas supplying portion, the second reaction gas supplying portion, and the laser beam irradiation portion; and a vacuum evacuation portion that evacuates an inside of the vacuum chamber. The first reaction gas supplying portion, the second reaction gas supplying portion, and the laser beam irradiation portion are arranged so that the substrate is positioned in order of a first process area where the first reaction gas is supplied, a second process area where the second reaction gas is supplied, and an irradiation area to which the laser beam is irradiated during the relative rotation.

According to a second aspect of the present invention, there is provided a film deposition method for depositing a film on a substrate by performing a cycle of alternately supplying at least two kinds of reaction gases that react with each other to the substrate to produce a layer of a reaction product in a vacuum chamber. The film deposition method includes steps of: placing the substrate on a table that is provided in the vacuum chamber and has a substrate receiving area in which the substrate is placed; vacuum evacuating an inside of the vacuum chamber; relatively rotating the table and a combination of a first reaction gas supplying portion, a second reaction gas supplying portion, and a laser beam irradiation portion; supplying a first reaction gas from the first reaction gas supplying portion to the substrate; supplying a second reaction gas from the second reaction gas supplying portion to the substrate; and irradiating a laser beam to an area spanning from one edge to another edge of the substrate in the substrate receiving area along a direction from an inner side to an outer side of the table.

According to a third aspect of the present invention, there is provided a storage medium storing a computer program to be used in a film deposition apparatus for depositing a film on a substrate by performing a cycle of alternately supplying at least two kinds of reaction gases that react with each other to the substrate to produce a layer of a reaction product in a vacuum chamber, the computer program includes a group of instructions that cause the film deposition apparatus to perform the film deposition method of the second aspect.

### BRIEF DESCRIPTION OF THE DRAWINGS

FIG. 1 is a cross-sectional view of a film deposition apparatus according to an embodiment of the present invention, taken along I-I′ line in FIG. 3;

FIG. 2 is a perspective view schematically illustrating an inner configuration of the film deposition apparatus of FIG. 1;

FIG. 3 is a plan view of the film deposition apparatus of FIG. 1;

FIG. 4 is a cross-sectional view of the film deposition apparatus of FIG. 1, illustrating process areas and a separation area;

FIG. 5 is a cross-sectional view

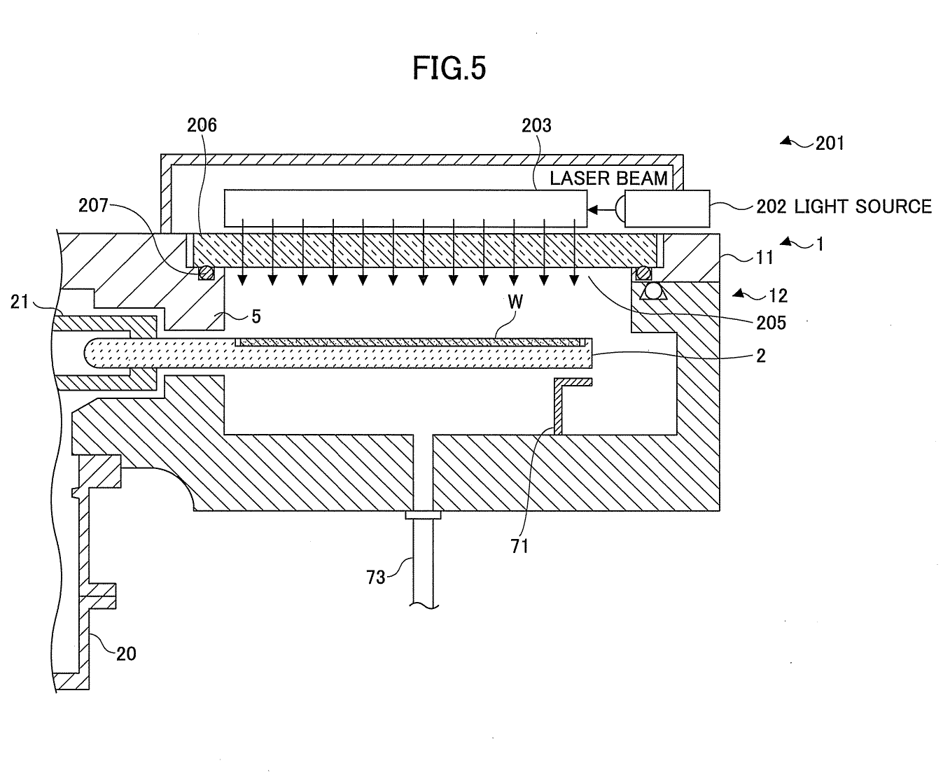

FIG. 6 illustrates a relationship between irradiation energy density of a laser beam from a laser beam irradiation portion and a wafer temperature;

FIG. 7 is a plan view schematically illustrating a laser beam irradiation area to which the laser beam is irradiated from the laser beam irradiation portion;

FIG. 8 is an explanatory view for explaining how a separation gas or a purge gas flows in the film deposition apparatus of FIG. 1;

FIG. 9 is a schematic view illustrating how a reaction product is produced;

FIG. 10 is an explanatory view illustrating how a first reaction gas and a second reaction gas are separated by the separation gas;

FIG. 11 is a cross-sectional view schematically illustrating a film deposition apparatus according to another embodiment of the present invention;

FIG. 12 is an explanatory view for explaining a size of a convex portion used in the separation area; and

FIG. 13 is a cross-sectional view illustrating a film deposition apparatus according to yet another embodiment of the present invention.

### DETAILED DESCRIPTION OF THE PREFERRED EMBODIMENT

According to an embodiment of the present invention, a film deposition apparatus, where a film is deposited on a substrate by relatively rotating the substrate and reaction gas supplying portions, thereby alternately supplying at least two kinds of reaction gases to the substrate, is provided with a laser beam irradiation portion that is provided opposing the substrate receiving area to irradiate a laser beam to an area spanning from one edge to another edge of the substrate receiving area along a direction from an inner side to an outer side of the table. Because the laser beam irradiation portion is also rotated in relation to the substrate, the substrate can be quickly heated when the substrate passes through the irradiated area, so that a reaction product of the reaction gases is produced on the substrate. Therefore, energy consumption required for heating the substrate in order to produce the reaction product, can be reduced. In addition, a chemical alteration process of the reaction product on the substrate can be performed, in addition to or instead of the film deposition process employing the laser beam irradiation portion, so that a densified thin film having a reduced level of impurities can be obtained.

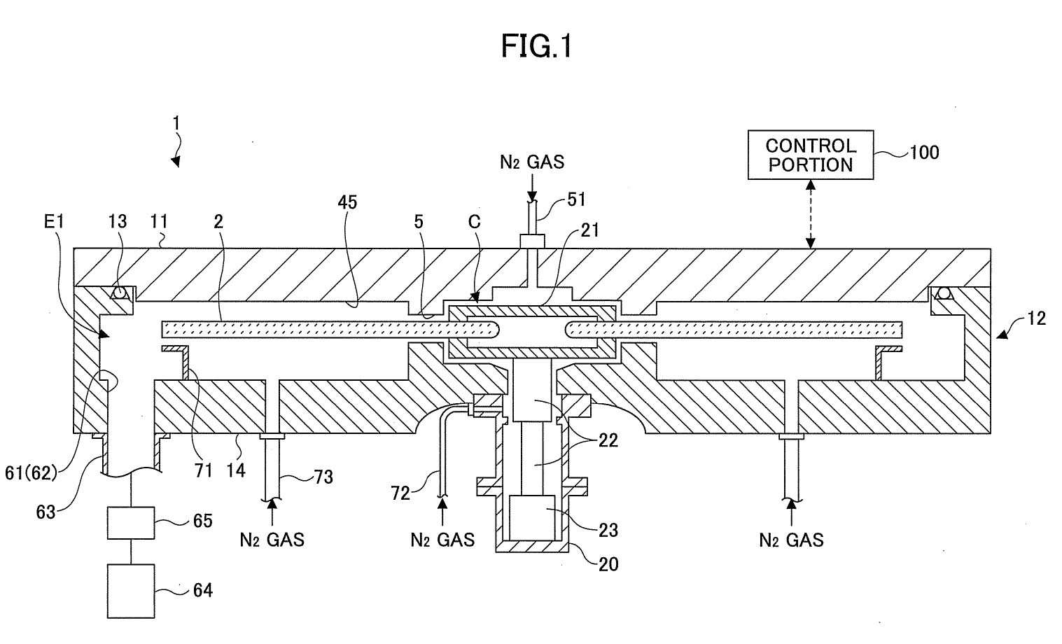

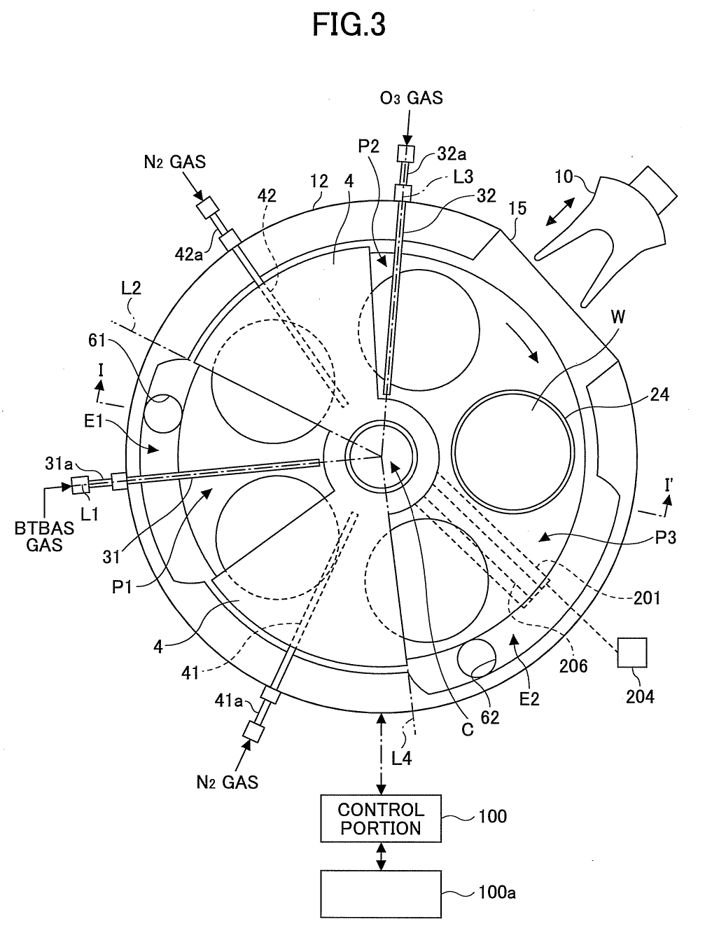

Referring to FIG. 1, which is a cross-sectional view taken along I-I′ line in FIG. 3, a film deposition apparatus according to an embodiment of the present invention has a vacuum chamber 1 having a flattened cylinder shape whose top view is substantially a circle, and a turntable 2 that is located inside the chamber 1 and has a rotation center at a center of the vacuum chamber 1. The vacuum chamber 1 is made so that a ceiling plate 11 can be separated from a chamber body 12. The ceiling plate 11 is pressed onto the chamber body 12 via a sealing member such as an O-ring 13 when the vacuum chamber 1 is evacuated to reduced pressures. Therefore, the air-tightness between the ceiling plate 11 and the chamber body 12 via the O-ring 13 is certainly maintained. On the other hand, the ceiling plate 11 can be brought upward by a driving mechanism (not shown) when the ceiling plate 11 has to be removed from the chamber body 12.

The turntable 2 is rotatably fixed in the center onto a core portion 21 having a cylindrical shape. The core portion 21 is fixed on a top end of a rotational shaft 22 that extends in a vertical direction. The rotational shaft 22 goes through a bottom portion 14 of the chamber body 12 and is fixed at the lower end to a driving mechanism 23 that can rotate the rotational shaft 22 clockwise, in this embodiment. The rotational shaft 22 and the driving mechanism 23 are housed in a case body 20 having a cylinder with a bottom. The case body 20 is hermetically fixed to a bottom surface of the bottom portion 14, which isolates an inner environment of the case body 20 from an outer environment.

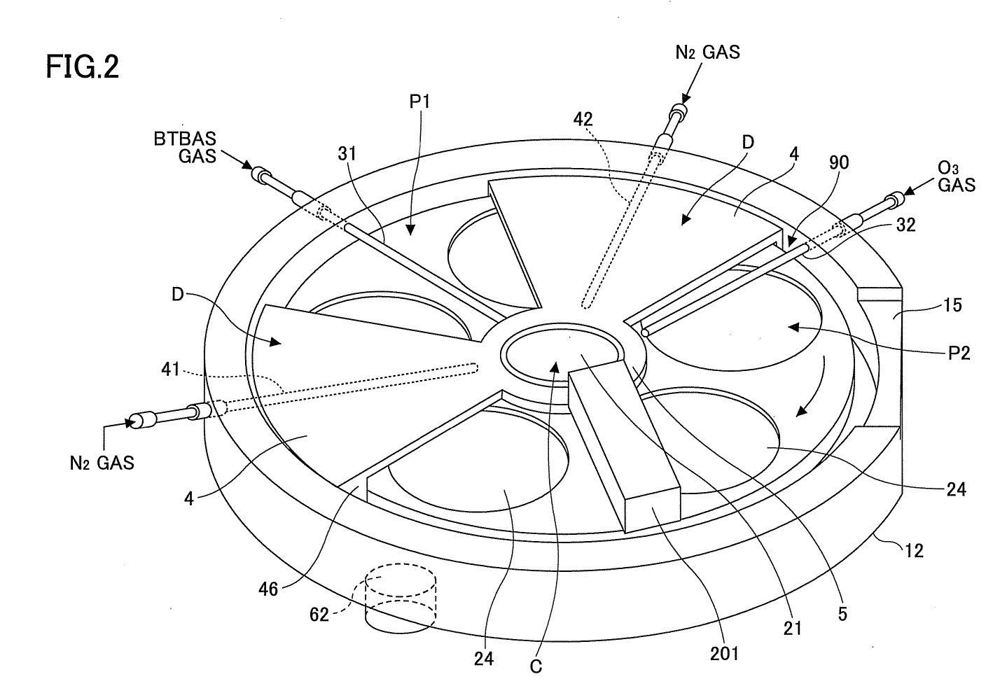

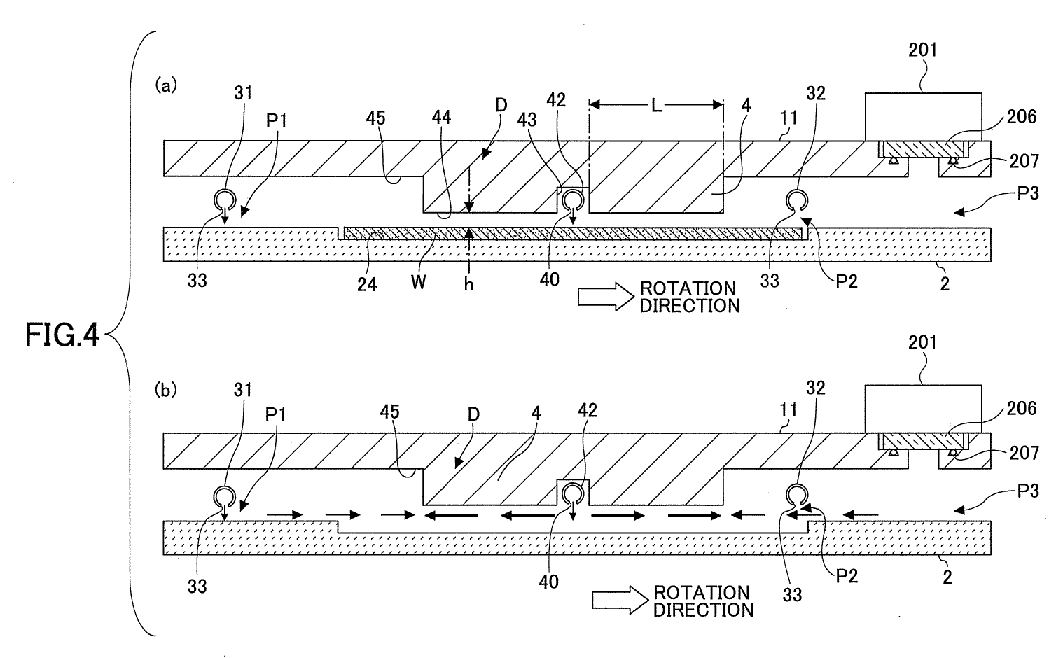

As shown in FIGS. 2 and 3, plural (e.g., five) circular concave portions 24, each of which receives a semiconductor wafer (referred to a wafer hereinafter) W, are formed along a rotation direction (circumferential direction) of and in a top surface of the turntable 2, although only one wafer W is illustrated in FIG. 3, for convenience of illustration. A section (a) of FIG. 4 is a projected cross-sectional diagram taken along a part of a circle concentric to the turntable 2. As shown in the drawing, the concave portion 24 has a diameter slightly larger, for example, by 4 mm than the diameter of the wafer W and a depth equal to a thickness of the wafer W. Therefore, when the wafer W is placed in the concave portion 24, a surface of the wafer W is at the same elevation of a surface of an area of the turntable 2, the area excluding the concave portions 24. If there is a relatively large step between the area and the wafer W, gas flow turbulence is caused by the step. Therefore, it is preferable from a viewpoint of across-wafer uniformity of a film thickness that the surfaces of the wafer W and the turntable 2 are at the same elevation. While “the same elevation” may mean here that a height difference is less than or equal to about 5 mm, the difference has to be as close to zero as possible to the extent allowed by machining accuracy. In the bottom of the concave portion 24 there are formed three through holes (not shown) through which three corresponding lift pins are moved upward or downward. The lift pins support a back surface of the wafer W and raises/lowers the wafer W.

The concave portions 24 are wafer W receiving areas provided to position the wafers W and to keep the wafers W in order not to be thrown out by centrifugal force caused by rotation of the turntable 2. However, the wafer W receiving areas are not limited to the concave portions 24, but may be realized by guide members that are located at predetermined angular intervals on the turntable 2 to hold the edges of the wafers W. Alternatively, when the wafer W is firmly pulled onto the turntable 2 by an electrostatic chuck mechanism, the wafer W receiving area may be defined by an area where the wafer W is pulled onto the turntable 2.

As shown in FIGS. 2 and 3, a first reaction gas nozzle 31, a second reaction gas nozzle 32, and separation gas nozzles 41, 42, which are made of, for example, quartz, are arranged at predetermined angular intervals along the circumferential direction of the vacuum chamber 1 and above the turntable 2, and extend in radial directions. In the illustrated example, the separation gas nozzle 41, the first reaction gas nozzle 31, the separation gas nozzle 42, and the second reaction gas nozzle 32 are arranged clockwise (or along the rotation direction of the turntable 2) in this order from a transfer opening 15 (described later). These gas nozzles 31, 32, 41, and 42 are provided in order to horizontally extend with respect to the wafer W from an outer circumferential wall portion of the vacuum chamber 1 toward the rotation center of the turntable 12. Each of the nozzles 31, 32, 41, and 42 penetrate the circumferential wall portion of the chamber body 12 and are supported by attaching their base ends, which are gas inlet ports 31a, 32a, 41a, 42a, respectively, on the outer circumference wall of the circumferential wall portion. The first reaction gas nozzle 31 serves as a first reaction gas supplying portion; the second reaction gas nozzle 32 serves as a second reaction gas supplying portion; and the separation gas nozzles 41 and serve as separation gas supplying portions. An irradiation area P3 where a laser beam is irradiated to the wafer W from a laser beam irradiation portion 201 (described later) provided above the ceiling plate 11 is defined between the second reaction nozzle 32 and the separation gas nozzle 41 (specifically, an upper edge of a separation area D (described later) where the separation gas nozzle 41 is provided, the upper edge being relative to the rotation direction of the turntable 2). The laser beam irradiation portion 201 and the irradiation area P3 are described later.

Although the reaction gas nozzles 31, 32 and the separation gas nozzles 41, 42 are introduced into the vacuum chamber 1 from the circumferential wall portion of the vacuum chamber 1 in the illustrated example, these nozzles 31, 32, 41, 42 may be introduced from a ring-shaped protrusion portion 5 (described later). In this case, an L-shaped conduit may be provided in order to be open on the outer circumferential surface of the protrusion portion 5 and on the outer top surface of the ceiling plate 11. With such an L-shaped conduit, the nozzle 31 (32, 41, 42) can be connected to one opening of the L-shaped conduit inside the vacuum chamber 1 and the gas inlet port 31a (32a, 41a, 42a) can be connected to the other opening of the L-shaped conduit outside the vacuum chamber 1.

In this embodiment, the first reaction gas nozzle 31 is connected via a flow rate controlling valve (not shown) to a gas supplying source (not shown) of bis (tertiary-butylamino) silane (BTBAS), which is a first source gas, and the second reaction gas nozzle 32 is connected via a flow rate controlling valve (not shown) to a gas supplying source (not shown) of O₃ (ozone) gas, which is a second source gas. The separation gas nozzles 41, 42 are connected via flow rate controlling valves (not shown) to separation gas sources (not shown) of nitrogen (N₂) gas.

The reaction gas nozzles 31, 32 have plural ejection holes 33 to eject the corresponding source gases downward. The plural ejection holes 33 are arranged in longitudinal directions of the reaction gas nozzles 31, 32 at predetermined intervals. The ejection holes 33 have an inner diameter of about 0.5 mm, and are arranged at intervals of about 10 mm in this embodiment. In addition, the separation gas nozzles 41, 42 have plural ejection holes 40 to eject the separation gases downward from the plural ejection holes 40. The plural ejection holes 40 are arranged at predetermined intervals in longitudinal directions of the separation gas nozzles 41, 42. The ejection holes 40 have an inner diameter of about 0.5 mm, and are arranged at intervals of about 10 mm in this embodiment. A distance between the ejection holes 33 of the reaction gas nozzles 31, 32 and the wafer W is, for example, 1 to 4 mm, and preferably 2 mm, and a distance between the gas ejection nozzle 40 of the separation gas nozzles 41, 42 and the wafer W is, for example, 1 to 4 mm, and preferably 3 mm. In addition, an area below the reaction gas nozzle 31 is a first process area P1 in which the BTBAS gas is adsorbed on the wafer W, and an area below the reaction gas nozzle 32 is a second process area P2 in which the O₃ gas is adsorbed on the wafer W.

The separation gas nozzles 41, 42 are provided in separation areas D that are configured to separate the first process area P1 and the second process area P2. In each of the separation areas D, there is provided a convex portion 4 on the ceiling plate 11, as shown in FIGS. 2 through 4. The convex portion 4 has a top view shape of a truncated sector and is protruded downward from the ceiling plate 11. The inner (or top) arc is coupled with the protrusion portion 5 and an outer (or bottom) arc lies near and along the inner circumferential wall of the chamber body 12. In addition, the convex portion 4 has a groove portion 43 that extends in the radial direction and substantially bisects the convex portion 4. The separation gas nozzles 41, 42 are located in the corresponding groove portions 43. A circumferential distance between the center axis of the separation gas nozzle 41 (42) and one side of the sector-shaped convex portion 4 is substantially equal to the other circumferential distance between the center axis of the separation gas nozzle 41 (42) and the other side of the sector-shaped convex portion 4.

Incidentally, while the groove portion 43 is formed in order to bisect the convex portion 4 in this embodiment, the groove portion 42 is formed so that an upstream side of the convex portion 4 relative to the rotation direction of the turntable 2 is wider, in other embodiments.

With the above configuration, there are flat low ceiling surfaces 44 (first ceiling surfaces) on both sides of the separation gas nozzles 41, 42, and high ceiling surfaces 45 (second ceiling surfaces) outside of the corresponding low ceiling surfaces 44, as shown in Section (a) of FIG. 4. The convex portion 4 (ceiling surface 44) provides a separation space, which is a thin space, between the convex portion 4 and the turntable 2 in order to impede the first and the second gases from entering the thin space and from being mixed.

Referring to Section (b) of FIG. 4, the O₃ gas, which is ejected from the reaction gas nozzle 32, is impeded from entering the space between the convex portion 4 and the turntable 2 from an upstream side along the rotation direction of the turntable 2, and the BTBAS gas, which is ejected from the reaction gas nozzle 31, is impeded from entering the space between the convex portion 4 and the turn table 2 from a downstream side along the rotation direction of the turntable 2. “The gases being impeded from entering” means that the N₂ gas as the separation gas ejected from the separation gas nozzle 41 flows between the first ceiling surfaces 44 and the upper surface of the turntable 2 and flows out to a space below the second ceiling surfaces 45, which are adjacent to the corresponding first ceiling surfaces 44 in the illustrated example, so that the gases cannot enter the separation space from the space below the second ceiling surfaces 45. “The gases cannot enter the separation space” means not only that the gases are completely prevented from entering the separation space, but that the gases cannot proceed farther toward the separation gas nozzle 41 and thus be mixed with each other even when a fraction of the reaction gases enter the separation space. Namely, as long as such effect is demonstrated, the separation area D is to separate atmospheres of the first process area P1 and the second process area P2. Therefore, a degree of thiness in the thin separation space is determined so that a pressure difference between the thin separation space and the spaces adjacent to the thin separation space (spaces below the second ceiling surfaces 45) can demonstrate the effect of “the gases cannot enter the separation space”, and a specific size of the thin separation space depends on an area of the convex portion 4 and the like. Incidentally, the BTBAS gas or the O₃ gas adsorbed on the wafer W can pass through and below the convex portion 4. Therefore, the gases in “the gases being impeded from entering” mean the gases in a gaseous phase.

Next, the laser beam irradiation portion 201 is explained. The laser beam irradiation portion 201 is provided to irradiate a laser beam to the wafer W on the turntable 2, thereby quickly heating the upper surface of the wafer W. The laser beam irradiation portion 201 is located between the second reaction gas nozzle 32 and the separation area D downstream of the second reaction gas nozzle 32 relative to the rotation direction of the turntable 2, as shown in FIGS. 2 and 3. In addition, the laser beam irradiation portion 201 is arranged above the turntable 2 in order to be parallel with the turntable 2. The laser beam irradiation portion 201 is provided with a light source 202 that emits the laser beam in a horizontal (traverse) direction from the outer circumferential side to the center side of the vacuum chamber 1 (or the rotation center of the turntable 2), and an optical member 203 that guides the laser beam from the horizontal to the downward directions, and expands the laser beam so that a stripe-shaped area spanning from the inner side edge through the outer side edge of the concave portion 24 of the turntable 2 is irradiated by the expanded laser beam. Incidentally, the ceiling plate 11 is omitted in FIG. 2 in order to clearly illustrate a positional relationship between the laser beam irradiation portion 201, the second reaction gas nozzle 32, and the separation area D, and the laser beam irradiation portion 201 is just simply illustrated in FIGS. 1 and 2.

The light source 202 is configured to emit a laser beam having, for example, a wavelength in ultraviolet through infrared regions of the spectrum (a wavelength of 808 nm in this embodiment) and irradiation energy density of about 17 through about 100 J/cm², with electric power supplied from an electric power source 204, so that the upper surface of the wafer W is quickly heated to temperatures from 200 through 1200° C. The light source 202 may be a gas laser device or a semiconductor laser device.

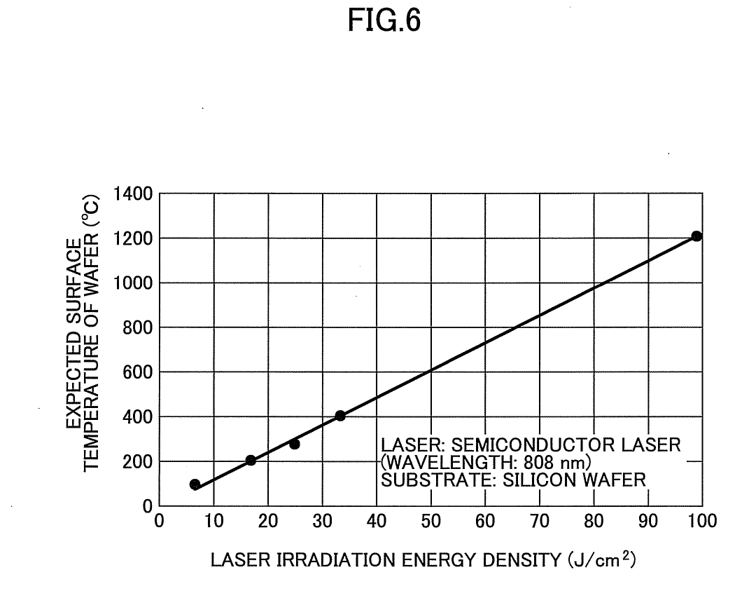

The irradiation energy density (J/cm²) of the laser beam is expressed by a product of electric power density (W/cm²) and an irradiation time(s). The electric power density is expressed by P/S, where P (W) is power of the laser beam and S is an area irradiated with the laser beam. The area corresponds to an irradiation area P3 (described later) in this embodiment. The irradiation time is expressed by 60×l/(2πrN), where l (cm) is an arc length of the irradiation area, r (cm) is a radius of the turntable 2, and N (revolution per minute (rpm)) is a rotation speed of the turntable 2. Therefore, the irradiation energy density should be determined by taking a size of the film deposition apparatus, and film deposition conditions into consideration. Incidentally, because the upper surface temperature of the wafer W is expected to be in a proportional relationship with the irradiation energy density, as shown in FIG. 6, the upper surface of the wafer W can be set at a desired temperature by determining the irradiation energy density in the above-mentioned range.

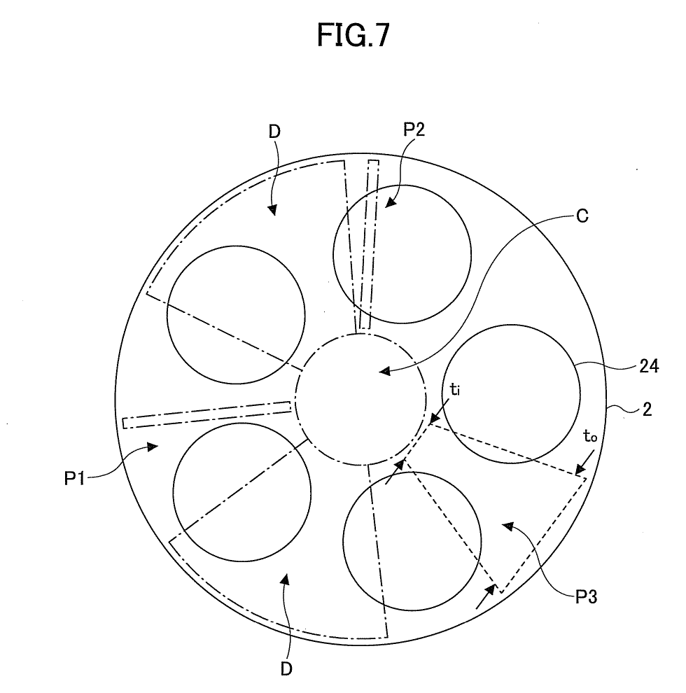

The optical member 203 includes, for example, a beam splitter, a convex or concave cylindrical lens, a collimate lens, and the like, and is configured in order to expand the laser beam so that a stripe-shaped (or a square-shaped) area (the irradiation area P3) spans from the outer side edge to the inner side edge of the wafer W in the concave portion 24 of the turntable 2 in a radius direction of the turntable 2. In addition, the irradiation area P3 has a predetermined width in the circumferential direction of the turntable 2, and thus occupies a localized area rather than the entire upper surface of the turntable 2, as shown in FIG. 7. In this case, because a circumferential speed of the turntable 2 becomes greater toward the outer circumferential edge of the turntable 2, a width of the irradiation area P3 preferably becomes greater toward the outer circumferential edge of the turntable 2, so that the irradiation time of the laser beam that irradiates the wafer W is equal in a direction from the inner edge to the outer edge of the wafer W. For example, the irradiation area P3 may have a trapezoidal shape. In this embodiment, an inner width ti (see FIG. 7) of the irradiation area P3 is about 100 mm, and an outer width of the irradiation area P3 is about 300 mm. Incidentally, the irradiation area P3 is illustrated with a hatch, and other members but the turntable 3 is omitted in FIG. 7.

In addition, a square-shaped opening 205 is formed in the ceiling plate 11 in such a manner that the laser beam is emitted into the vacuum chamber 1 from the laser beam irradiation portion 201 so that the area from the inner to the outer of the turntable 2 is illuminated. In addition, the opening 205 becomes, for example, wider toward the circumference of the ceiling plate 11. The opening 205 is covered by a transparent window 206 in an air-tight manner. Specifically, a sealing member 207 is provided between the ceiling plate 11 and a lower and peripheral surface of the transparent window 206. The opening 205 is determined, for example, to have substantially the same size as the irradiation area P3 in order that the irradiation area P3 is certainly obtained, and a size of the transparent window 206 is determined to be larger so that the sealing member 207 is held between the transparent window 206 and the ceiling plate 11. Specifically, the opening 205 has a width ti of about 100 mm in the inner side of the ceiling plate 11 and a width to of about 300 mm in the outer side of the ceiling plate 11.

In this embodiment, the wafer W to be placed on the concave portion 24 has a diameter of 300 mm. In this case, the convex portion 4 has a circumferential length of, for example, about 146 mm along an inner arc (a boundary between the convex portion 4 and a protrusion portion 5 (described later)) that is at a distance 140 mm from the rotation center of the turntable 2, and a circumferential length of, for example, about 502 mm along an outer arc corresponding to the outermost portion of the concave portion 24 of the turntable 2. In addition, a circumferential length from one side wall of the convex portion 4 through the nearest side of the separation gas nozzle 41 (42) along the outer arc is about 246 mm.

In addition, as shown in Section (a) of FIG. 4, the height h of the back surface of the convex portion 4, or the ceiling surface 44, with respect to the upper surface of the turntable 2 (or the wafer W) is, for example, about 0.5 mm through about 10 mm, and preferably about 4 mm. In this case, the rotation speed of the turntable 2 is, for example, 1 through 500 rotations per minute (rpm). In order to ascertain the separation function performed by the separation area D, the size of the convex portion 4 and the height h of the ceiling surface 44 from the turntable 2 may be determined depending on the pressure in the chamber 1 and the rotation speed of the turntable 2 through experimentation. Incidentally, the separation gas is N₂ in this embodiment but may be an inert gas such as He and Ar, or H2 in other embodiments, as long as the separation gas does not affect the deposition of silicon dioxide.

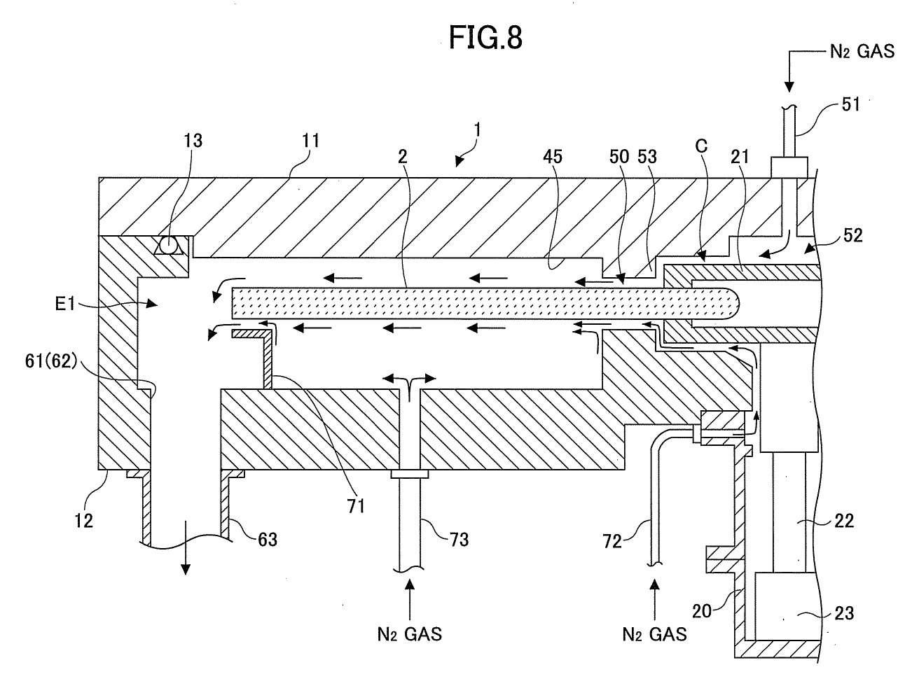

On the other hand, as shown in FIGS. 4 and 8, a ring-shaped protrusion portion 5 is provided on a back surface of the ceiling plate 11 so that the inner circumference of the protrusion portion 5 faces the outer circumference of the core portion 21 that fixes the turntable 2. The protrusion portion 5 opposes the turntable 2 at an outer area of the core portion 21. In addition, the protrusion portion 5 is integrally formed with the convex portion 4 so that a back surface of the protrusion portion 5 is at the same height as that of a back surface of the convex portion 4 from the turntable 2. Incidentally, the convex portion 4 is formed not integrally with but separately from the protrusion portion 5 in other embodiments. Additionally, FIGS. 2 and 3 show the inner configuration of the vacuum chamber 1 as if the vacuum chamber 1 is severed along a horizontal plane lower than the ceiling surface 45 and higher than the reaction gases 31, 32.

The separation area D is configured by forming the groove portion 43 in a sector-shaped plate to be the convex portion 4, and locating the separation gas nozzle 41 (42) in the groove portion 43 in the above embodiment. However, without being limited to this, two sector-shaped plates may be attached on the lower surface of the ceiling plate 11 by screws so that the two sector-shaped plates are located on both sides of the separation gas nozzle 41 (32).

As stated above, the first ceiling surface 44 and the second ceiling surface 45 higher than the first ceiling plates are alternatively arranged in the circumferential direction in the vacuum chamber 1. Note that FIG. 1 is a cross-sectional view of the vacuum chamber 1, which illustrates the two higher ceiling surfaces 45. As shown in FIG. 2, the convex portion 4 has at a circumferential portion (or at an outer side portion toward the inner circumferential surface of the chamber body 12) a bent portion 46 that bends in an L-shape and fills a space between the turntable 2 and the chamber body 12. Although there are slight gaps between the bent portion 46 and the turntable 2 and between the bent portion 46 and the chamber body 12 because the convex portion 4 is attached on the back surface of the ceiling portion 11 and removed from the chamber body 12 along with the ceiling portion 11, the bent portion 46 substantially fills out a space between the turntable 2 and the chamber body 12, thereby reducing intermixing of the first reaction gas (BTBAS) ejected from the first reaction gas nozzle 31 and the second reaction gas (ozone) ejected from the second reaction gas nozzle 32 through the space between the turntable 2 and the chamber body 12. The gaps between the bent portion 46 and the turntable 2 and between the bent portion 46 and the chamber body 12 may be the same as the height h of the ceiling surface 44 from the turntable 2. In the illustrated example, an inner circumferential surface of the bent portion 46 may serve as an inner circumferential wall of the chamber body 12.

While the inner circumferential surface of the chamber body 12 is close to an outer circumferential surface in the separation area D, the chamber body 12 has indented portions respectively in the first and the second process areas P1, P2, or below the corresponding ceiling surfaces 45 as shown in FIG. 1. The dented portion in pressure communication with the first process area P1 is referred to an evacuation area E1 and the dented portion in pressure communication with the second process area P2 is referred to an evacuation portion E2, hereinafter. As shown in FIGS. 1 and 3, an evacuation port 61 is formed in a bottom of the evacuation area E1, and an evacuation port 62 is formed at a bottom of the evacuation area E2. As shown in FIG. 1, the evacuation ports 61, 62 are connected to a common vacuum pump 64 serving as an evacuation portion via corresponding evacuation pipes 63. Reference symbol 65 denotes a pressure adjusting portion, which is provided in each of evacuation pipes 63.

In this embodiment, the evacuation ports 61, 62 are positioned on both sides of the separation areas D, when seen from the above, as shown in FIG. 3, in order to strengthen the separation function performed by the separation areas D. Specifically, the evacuation port 61 is located between the first process area P1 and the separation area D being adjacent the first process area P1 in a downstream side of the rotation direction of the turntable 2, and the evacuation port 62 is located between the second process area P2 and the separation area D being adjacent the second process area P2 in a downstream side of the rotation direction of the turntable 2. With these configurations, the BTBAS gas is mainly evacuated from the evacuation port 61, and the O₃ gas is mainly evacuated from the evacuation port 62. In the illustrated example, the evacuation port 61 is provided between the reaction gas nozzle 31 and an extended line along a straight edge of the convex portion 4 located downstream relative to the rotation direction of the turntable 2 in relation to the reaction gas nozzle 31, the straight edge being closer to the reaction gas nozzle 31. In addition, the evacuation port 62 is provided between the reaction gas nozzle 32 and an extended line along a straight edge of the convex portion 4 located downstream relative to the rotation direction of the turntable 2 in relation to the reaction gas nozzle 32, the straight edge being closer to the reaction gas nozzle 32. In other words, the evacuation port 61 is provided between a straight line L1 shown by a chain line in FIG. 3 that extends from the center of the turntable 2 along the reaction gas nozzle 31 and a straight line L2 shown by a chain line in FIG. 3 that extends from the center of the turntable 2 along the straight edge on the upstream side of the convex portion 4 concerned. Additionally, the evacuation port 62 is provided between a straight line L3 shown by a chain line in FIG. 3 that extends from the center of the turntable 2 along the reaction gas nozzle 32 and a straight line L4 shown by a chain line in FIG. 3 that extends from the center of the turntable 2 along the straight edge on the upstream side of the convex portion 4 concerned.

While the two evacuation ports 61, 62 are formed in the chamber body 12 in this embodiment, three evacuation ports may be formed in other embodiments. In the illustrated example, the evacuation ports 61, 62 are provided lower than the turntable 2 so that the vacuum chamber 1 is evacuated through a gap between the circumference of the turntable 2 and the inner circumferential wall of the chamber body 12. However, the evacuation ports 61, 62 may be provided in the circumferential wall of the chamber body 12. When the evacuation portions 61, 62 are provided in the circumferential wall, the evacuation ports 61, 62 may be located higher than the top surface of the turntable 2. In this case, gases flow along the top surface of the turntable 2 and into the evacuation ports 61, 62 located higher than the top surface of the turntable 2. Therefore, it is advantageous in that particles in the vacuum chamber 1 are not blown upward by the gases, compared to when the evacuation ports are provided, for example, in the ceiling plate 11.

As shown in FIGS. 1 and 8, a cover member 71 is provided beneath the turntable 2 and near the outer circumference of the turntable 2, so that an atmosphere below the turntable 2 is partitioned from an atmosphere from the an area above the turntable 2 through the evacuation area E1 (or E2). An upper edge portion of the cover member 71 is bent outward into a flange shape. The flange shape portion is arranged so that a slight gap is maintained between the lower surface of the turntable 2 and the flange shape portion in order to reduce gas that flows into the inside of the cover member 71.

The bottom portion 14 is raised in its area so that the bottom portion 14 comes close to but leaves slight gaps with respect to the core portion 21 and a center and lower area of the turntable 2. In addition, the bottom portion 14 has a center hole through which the rotational shaft 22 passes and leaves a gap between the inner circumferential surface of the center hole and the rotational shaft 22. This gap is in gaseous communication with the case body 20. A purge gas supplying pipe 72 is connected to the case body 20 in order to supply N₂ gas serving as a purge gas to the inside of the case body 20. In addition, plural purge gas supplying pipes 73 are connected at plural positions with predetermined circumferential intervals to the bottom portion 14 of the chamber body 12 in order to supply a purge gas to the area below the turntable 2.

By providing the purge gas supplying pipes 72, 73 in such manners, a space extending from the case body 20 through the area below the turntable 2 is purged with N₂ purge gas, which is then evacuated through the gap between the turntable 2 and the cover member 71 to the evacuation areas E1 (E2), as illustrated by arrows in FIG. 8. With this, because the BTBAS (O₃) gas supplied to the first (second) process area P1 (P2) cannot flow through the space below the turntable 2 to the second (first) process area P2 (P1) to be intermixed with the O₃ (BTBAS) gas, the N₂ gas serves as a separation gas

Referring to FIG. 8, a separation gas supplying pipe 51 is connected to a center portion of the ceiling plate 11 of the vacuum chamber 1. From the separation gas supplying pipe 51, N₂ gas as a separation gas is supplied to a space 52 between the ceiling plate 11 and the core portion 21. The separation gas supplied to the space 52 flows through a narrow gap 50 between the protrusion portion 5 and the turntable 2, and along the upper surface of the turntable 2 toward the circumferential edge of the turntable 2. Because the space 52 and the gap 50 are filled with the separation gas, the BTBAS gas and the O₃ gas are not intermixed through the center portion of the turntable 2. In other words, the film deposition apparatus according to this embodiment is provided with a center area C defined by a rotational center portion of the turntable 2 and the vacuum chamber 1 and configured to have an ejection opening for ejecting the separation gas toward the upper surface of the turntable 2 in order to separate atmospheres of the process area P1 and the process area P2. In the illustrated example, the ejection opening corresponds to the gap 50 between the protrusion portion 5 and the turntable 2.

In addition, a transfer opening 15 is formed in a side wall of the chamber body 12 as shown in FIGS. 2 and 3. Through the transfer opening 15, the wafer W is transferred into or out from the chamber 1 by a transfer arm 10 (FIGS. 3 and 8). The transfer opening 15 is provided with a gate valve (not shown) by which the transfer opening 15 is opened or closed. Because the wafer W is placed in the concave portion 24 as a wafer receiving portion of the turntable 2 when the concave portion 24 of the turntable 2 is at a position in alignment with the transfer opening 15, there are provided below the position lift pins and an elevation mechanism (not shown) that enables the lift pins to go through corresponding through-holes formed in the concave portion 24, thereby moving the wafer W upward or downward.

In addition, the film deposition apparatus according to this embodiment is provided with a control portion 100 that controls the film deposition apparatus. The control portion 100 includes a process controller composed of, for example, a computer. A memory device of the control portion 100 stores programs that cause the film deposition apparatus to perform a film deposition process and a film chemical alteration process described later. The programs include a group of instructions for causing the film deposition apparatus to perform operations described later. The programs are stored in a storage medium 100a (FIG. 3) such as a hard disk, a compact disk (CD), a magneto-optic disk, a memory card, a flexible disk, or the like, and installed into the control portion 100 from the storage medium 100a.

Next, an effect of this embodiment is described. First, when the gate valve (not shown) is opened, the wafer W is transferred into the vacuum chamber 1 through the transfer opening 15 by the transfer arm 10, and placed on the concave portion 24 of the turntable 2. Specifically, after the concave portion 24 is located in alignment with the transfer opening 15, the wafer W is brought into the vacuum chamber 1 and held above the concave portion 24 by the transfer arm 10. Next, the wafer W is received by the lift pins. After the transfer arm 10 is retracted from the vacuum chamber 1, the lift pins are brought down, so that the wafer W is placed in the concave portion 24. Such transfer-in of the wafer W is repeated by intermittently rotating the turntable 2, and five wafers W are placed in the corresponding concave portions 24 of the turntable 2. Subsequently, the transfer opening 15 is closed; the vacuum chamber 1 is evacuated to the lowest reachable pressure; the N₂ gas is supplied from the separation gas nozzles 41, 42 to the vacuum chamber 1 at predetermined rates, and from the separation gas supplying pipe 51 and the purge gas supplying pipe 72 at predetermined flow rates; and an inner pressure of the vacuum chamber 1 is set at a predetermined process pressure by the pressure adjusting portion 65. Then, the turntable 2 is rotated clockwise at a predetermined rotation speed. Next, the BTBAS gas and the O₃ gas are supplied from the reaction gas nozzle 31 and the reaction gas nozzle 32, respectively, and the laser beam is emitted from the laser beam irradiation portion 201 at an energy density of, for example, 67 J/cm² toward the turntable 2 by supplying electric power from the electric power source 204 (FIG. 3) to the laser beam irradiation portion 201, so that the irradiation area P3 in the turntable 2 is quickly heated to 800° C.

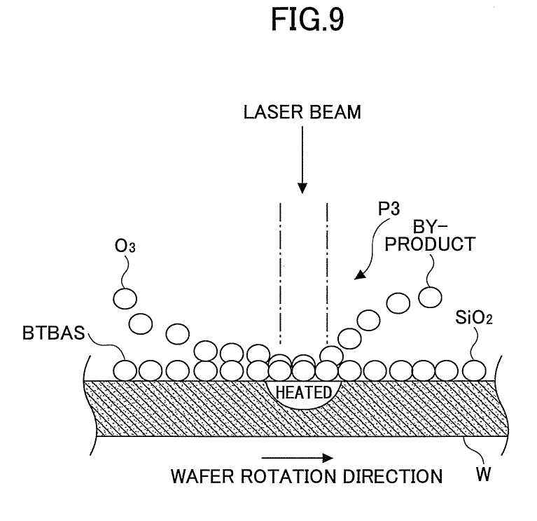

When the wafer W reaches the process area P1 due to the rotation of the turntable 2, the BTBAS gas is adsorbed on the wafer W. Next, the wafer W is exposed to the O₃ gas in the second process area P2. The O₃ gas flows toward the evacuation port 62 by suction force from the evacuation portion 62 and rotation of the turntable 2. When the wafer W reaches the irradiation area P3, the wafer W is quickly heated to, for example, 800° C., the BTBAS gas adsorbed on the wafer W and the O₃ gas are reacted with each other due to the heat, as schematically shown in FIG. 9. Namely, the BTBAS gas on the wafer W is oxidized by the O₃ gas, thereby forming one or more layers of silicon dioxide.

If the wafer W is heated by, for example, a heater rather than the laser beam to, for example, 350° C., groups of BTBAS molecules, for example, may remain, so that the resulting silicon oxide film contains impurities such as moisture (or OH groups) or organic substances. However, when the upper surface of the wafer W is quickly heated to such a high temperature by the laser beam, such impurities can be removed from the silicon oxide film substantially at the same time when the silicon oxide is formed, or the atoms of silicon and oxygen in the silicon oxide film may be re-arrayed so that the silicon oxide film is densified. In other words, the silicon oxide film is deposited and chemically altered at the same time. Therefore, the silicon oxide film so deposited is densified and more tolerant with respect to wet-etching, compared to a silicon oxide film deposited by a conventional ALD method. Incidentally, by-products of the reaction between the BTBAS gas and the O₃ gas are evacuated along with N₂ gas and O₃ gas through the evacuation port 62.

In such a manner, when the wafer W passes through the irradiation area P3 having a stripe shape, the deposition and the chemical alteration processes of silicon oxide are performed. Because the adsorption of the BTBAS gas, the adsorption of the O₃ gas, the film deposition process (oxidization of the BTBAS gas by the O₃ gas), and the chemical alteration are performed so that silicon oxide film is deposited in layer(s)-by-layer(s) manner, the silicon oxide film that is densified and tolerant with respect to wet-etching is obtained across the wafer W. In addition, such silicon oxide film has uniform properties along a thickness direction.

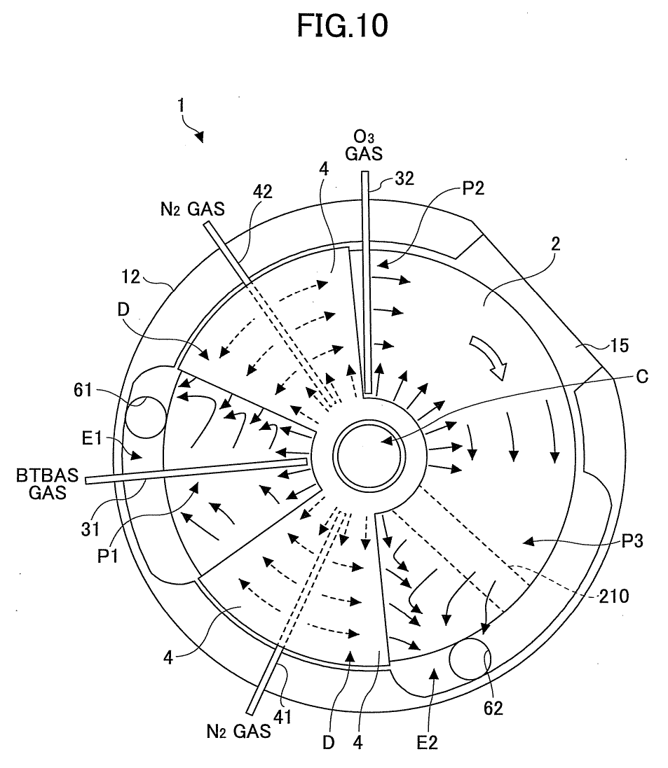

During the film deposition (and the chemical alteration), because N₂ gas serving as the separation gas is supplied to the separation area D between the first process area P1 and the second process area P2, and to the center area C, the BTBAS gas and the O₃ gas are evacuated without being intermixed with each other, as shown in FIG. 10. In addition, only the slight gaps remain between turntable 2 and the bent portion 46 in the separation areas D as described above, the BTBAS gas and the O₃ gas cannot be intermixed with each other through the gaps. Therefore, the first process area P1 and the second process area P2 are fully separated. The BTBAS gas is evacuated from the evacuation port 61, and the O₃ gas is evacuated from the evacuated port 62. As a result, the BTBAS gas and the O₃ gas are not intermixed in a gaseous phase.

In addition, because relatively large areas are formed corresponding to the spaces below the second ceiling surfaces 45 where the corresponding reaction gas nozzles 31, 32 are formed, and the evacuation ports 61, 62 are formed in the relatively large areas, a pressure in the thin area below the first (low) ceiling surface 44 is higher than a pressure in the relatively large area below the second (high) ceiling surface 45. Namely, the higher pressure below the first ceiling surface 44 provides a pressure wall against the BTBAS gas and the O₃ gas.

Incidentally, because the space below the turntable 2 is purged with N₂ gas, the BTBAS (O₃) gas that has flowed into the evacuation area E1 (E2) cannot reach the second (first) process area P2 (P1) through the space below the turntable 2.

An example of the process conditions is as follows. The rotation speed of the turntable 2 is, for example, 1 through 500 revolutions per minute when the wafer W having a diameter of 300 mm is processed; the process pressure is, for example, 1067 Pa (8 Torr); a flow rate of the BTBAS gas is, for example, 100 sccm; a flow rate of the O₃ gas is, for example, 10000 sccm; flow rates of the N₂ gas from the separation gas nozzles 41, 42 are, for example, 20000 sccm; and a flow rate of the N₂ gas from the separation gas supplying pipe 51 is, for example, 5000 sccm. In addition, the cycle number, which is the number of times which the wafer W passes through the first process area P1, the second process area P2, and the irradiation area P3, is, for example, 1000, although it depends on a target thickness of the silicon oxide film.

According to this embodiment, when the turntable 2 is rotated so that the BTBAS gas is adsorbed on the wafer W and then the O₃ gas is supplied to the wafer W to oxidize the BTBAS gas, thereby forming the silicon oxide film, the laser beam irradiation portion 201 that can irradiate the laser beam to the irradiation area P3 is used as a heating portion for heating the wafer W thereby to cause reaction of the O₃ gas and the BTBAS gas. With this, because the upper surface of the wafer W can be quickly heated, energy consumption required to cause the reaction can be reduced, compared to a case where, for example, a heater is used to heat the entire area of the turntable 2. In addition, because heat radiation from the heating portion (heater) can be reduced, the need for a cooling mechanism for the vacuum chamber 1 or the film deposition apparatus can be eliminated. Moreover, because the irradiation area P3 is defined as a square shape spanning over the diameter of the wafer W in a radius direction of the turntable 2, consumption energy for the laser beam emitting portion 201 can be reduced, compared to a case where the entire upper surface of the turntable 2 is irradiated and heated by the laser beam. Furthermore, because the upper surface of the wafer W is quickly heated to relatively high temperatures by the laser beam, the chemical alteration process can be performed at the same time of the film deposition process, so that the silicon oxide film can be densified and highly tolerant to wet-etching. Additionally, because the upper surface of the wafer W is quickly heated by the laser beam, thermal damage to the wafer W can be reduced, compared to a case where the wafer W is entirely heated by, for example, an annealing process.

In addition, because the chemical alteration process is performed at the same time of the film deposition process by the laser beam, the chemical alteration process is performed every cycle of the film deposition process. Namely, the chemical alteration process does not influence the film deposition process. Moreover, the chemical alteration process can be performed in a shorter period of time, compared to, for example, a case where the chemical alteration process is performed after the film deposition process is completed.

Moreover, even when a pattern is formed on the upper surface of the wafer W, for example, because the laser beam can reach features of the pattern (for example, a space between the lines), the irradiated surface of the wafer W can be uniformly heated by the laser beam, regardless of the pattern, so that uniform film deposition and chemical alteration can be realized.

In the film deposition apparatus according to an embodiment of the present invention, because plural wafers are placed on and along the rotation direction of the turntable 2 and alternately go through the first process area P1 and the second process area P2, thereby realizing the ALD process, a high throughput film deposition is performed. In addition, the film deposition apparatus according to an embodiment of the present invention is provided with the separation area D between the first process area P1 and the second process area P2 along the rotation direction of the turntable 2, the center area C defined by the rotation center portion of the turntable 2 and the vacuum chamber 1, and the evacuation ports 61, 62 that are in gaseous communication with the first and the second process areas P1, P2, respectively. Therefore, the reaction gases can be separated by the higher pressure created in the separation areas D (or below the first ceiling surface 44) with the N₂ gas ejected from the separation gas nozzles 41, 42; the reaction gases are also separated by the N₂ gas supplied from the center area C; and the reaction gases are evacuated from the corresponding evacuation ports 61, 62. As a result, the reaction gases are not intermixed with each other. Accordingly, a thin film having excellent properties can be obtained. Moreover, because the reaction gases are not intermixed in a gaseous phase, almost no or only a small amount of reaction products are deposited on an inner surface of the vacuum chamber 1, thereby reducing wafer contamination with particles.

A first reaction gas that may be used in the film deposition apparatus according to an embodiment of the present invention may be selected from dichlorosilane (DOS), hexachlorodisilane (HCD), Trimethyl Aluminum (TMA), tetrakis-ethyl-methyl-amino-zirconium (TEMAZ), tris(dimethyl amino) silane (3DMAS), tetrakis-ethyl-methyl-amino-hafnium (TEMAH), bis(tetra methyl heptandionate) strontium (Sr(THD)2), (methyl-pentadionate) (bis-tetra-methyl-heptandionate) titanium (Ti(MPD) (THD)), monoamino-silane, or the like. As a second reaction gas serving as an oxidation gas that oxides the above first gases, water vapor may be used. In addition, a first reaction gas containing silicon (for example, DCS gas) and a second reaction gas containing nitrogen (for example, ammonia gas) may be used to deposit a silicon nitrogen (SiN) film by employing the film deposition apparatus according to an embodiment of the present invention.

While the film deposition process and the chemical alteration process are performed with one laser beam irradiation portion 201 in this embodiment, plural (e.g., two) laser beam irradiation portions 201 may be arranged in the rotation direction of the turntable 2 in other embodiments. In this case, the plural laser beam irradiation portions 201 may be different, for example, in terms of wavelengths of the laser beams. Specifically, one of the plural laser beam irradiation portions 201, which is located upstream relative to the rotation direction of the turntable 2 (or near the transfer opening 15), may emit a laser beam in an infrared region of the spectrum, so that this laser beam irradiation portion 201 contributes to the film deposition process. In this case, this laser beam irradiation portion 201 may be a semiconductor laser device emitting an infrared laser beam. Another laser beam irradiation portion 201 located downstream relative to the rotation direction of the turntable 2 in relation to the laser beam irradiation portion 201 located upstream (or the first reaction gas nozzle 31) may emit a laser beam in an ultraviolet region of the spectrum, so that the other laser beam irradiation portion 201 contributes to the chemical alteration process. In this case, the other laser beam irradiation portion 201 may be an excimer laser. The silicon oxide film deposited at temperatures from 300° C. through 500° C. may contain a large amount of OH-groups, which may degrade quality of the silicon oxide film. Bond dissociation energy of the O—H bond is about 424 through 493 kJ/mol (4.4 eV through 5.1 eV), which corresponds to energy of the ultraviolet light whose wavelength is from 240 nm through 280 nm. Therefore, by irradiating the laser beam in the ultraviolet region of the spectrum onto the wafer W, the O—H groups are reduced or removed. For example, a KrF laser (248 nm) apparatus is preferably used as the ultraviolet laser beam irradiation portion 201 in order to chemically alter the silicon oxide film, while the film deposition process is performed with the infrared laser beam irradiation portion 201 that irradiates the infrared laser beam at an energy density of, for example, 30 J/cm². With these plural laser beam irradiation portions 201, the film deposition process and the chemical alteration process are separately performed by the corresponding laser beam irradiation portions 201 by adjusting corresponding energy densities. Even in this case, the above-mentioned effects and advantages are obtained.

Incidentally, the O₃ gas serving as an oxygen source at the time of film deposition is thermally decomposed into active oxygen species (O[3P]) that oxidize the BTBAS gas. When the KrF laser apparatus is used and the ultraviolet laser beam is irradiated onto the wafer W when the O₃ gas is supplied toward the wafer W, active species such as O[1D], which is more chemically active than O[3P], can be produced. The more chemically active species such as O[1D] may provide greater deposition rate. Therefore, use of the ultraviolet laser beam irradiation portion 201 may contribute to an increase in the film deposition rate. In addition, when a Xe₂ excimer laser apparatus (wavelength: 172 nm) is used, O₂ gas rather than O₃ gas can be activated into the active oxygen species such as O[3P] and O[1D]. Therefore, use of the Xe₂ excimer laser apparatus may eliminate the need for an O₃ gas generator (ozonizer), which leads to reduction in fabrication costs of the film deposition apparatus according to the present invention. Incidentally, an excimer lamp may be used instead of the ultraviolet laser beam irradiation portion 201.

In addition, while the film deposition process and the chemical alteration process are performed with the laser beam irradiation portions) 201 in this embodiment, the chemical alteration process may be performed with a plasma unit in other embodiments. In this case, while the infrared laser beam irradiation portion 201 is arranged in the above-mentioned manner in order to irradiate the irradiation area P3 with the infrared laser beam at an energy density of, for example, 38 J/cm², thereby quickly heating the wafer W to a temperature of, for example, 450° C., the plasma unit is arranged between the infrared laser beam irradiation portion 201 and the separation area D downstream relative to the rotation direction of the turntable 2 in relation to the laser beam irradiation portion 201 in order to chemically alter the deposited film. In addition, only the film deposition process may be performed with the laser beam irradiation portion 201 in the film deposition apparatus, and an annealing process (chemical alteration process) may be performed in a separate annealing apparatus. Even in this case, energy consumption can be reduced, compared to a case where the heater for heating the entire turntable 2 and the five wafers W on the turntable 2 is provided.

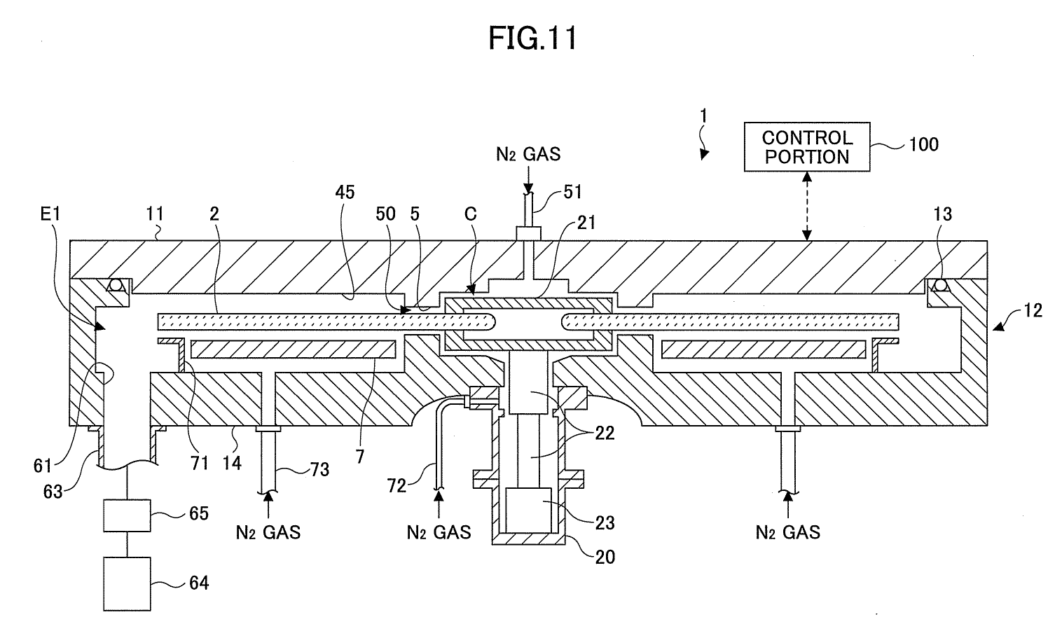

Furthermore, a heater for heating the wafers W on the turntable 2 may be provided in addition to the laser beam irradiation portion 201. Referring to FIG. 11, a heater unit 7 serving as a heating portion is provided in a space between the turntable 2 and the bottom portion 14 of the vacuum chamber 1. The heater unit 7 extends in the circumferential direction of the turntable 2 and heats the wafers W via the turntable 2, for example, at temperatures of about 450° C. In this example, the wavelength of the laser beam from the laser beam irradiation portion 201 and the energy density of the laser beam may be set in the same manner as in the case where the film deposition process and the chemical alteration process are performed with the laser beam irradiation portion 201.

In this case, the BTBAS gas is adsorbed on the wafer W in the first process area P1, and the adsorbed BTBAS gas is oxidized by the O₃ gas adsorbed on the wafer W in the second process area P2, thereby depositing the silicon oxide film. Then, the silicon oxide film is subject to the chemical alteration process in the irradiation area P3, so that impurities are removed from the silicon oxide film. Even in this case, energy consumption can be reduced, compared to a case where the film deposition process and the chemical alteration process are performed only with the laser beam irradiation portion 201. Namely, at least one of the film deposition process and the chemical alteration process is preferably performed with the laser beam irradiation portion 201. Alternatively, only the film deposition process may be performed with the heater unit 7 and the laser beam irradiation portion 201.

In addition, the laser beam emitted from the laser beam irradiation portion 201 is expanded to irradiate the trapezoidal shape irradiation area P3 by using the optical member 203 in this embodiment. However, the laser beam may be expanded to irradiate a sector shape irradiation area P3 whose arc length becomes longer closer to the circumferential edge of the turntable 2. Alternatively, the irradiation area P3 may have a line shape or a planar shape (e.g., a circular shape having the same diameter of the wafer W). In addition, the plural light sources 202 and the plural optical members 203 may be arranged on or above the ceiling plate 11 in a direction from the inner to the outer portions of the ceiling plate 11. Moreover, the laser beam from one light source 202 may be scanned in a radius direction of the turntable 2 by a mirror (not shown) while the wafer W is kept at a standstill for a moment under the transparent window 206 (FIG. 4). According to this, the entire wafer W is irradiated with the laser beam in such a manner that the wafer W is slightly moved, the laser beam is scanned, and such a procedure is repeated. Furthermore, the light source 202 may be a wavelength-tunable laser beam emitting apparatus. With this, a wavelength (or active laser media) can be changed depending on a film of a material to be deposited.

While the laser beam irradiation portion 201 is preferably arranged between the second reaction gas nozzle 32 and the straight side of the separation area D downstream relative to the rotation direction of the turntable 2 in relation to the second reaction gas nozzle 32 when seen from above, the laser beam irradiation portion 201 may be arranged above the second reaction gas nozzle 32, for example.

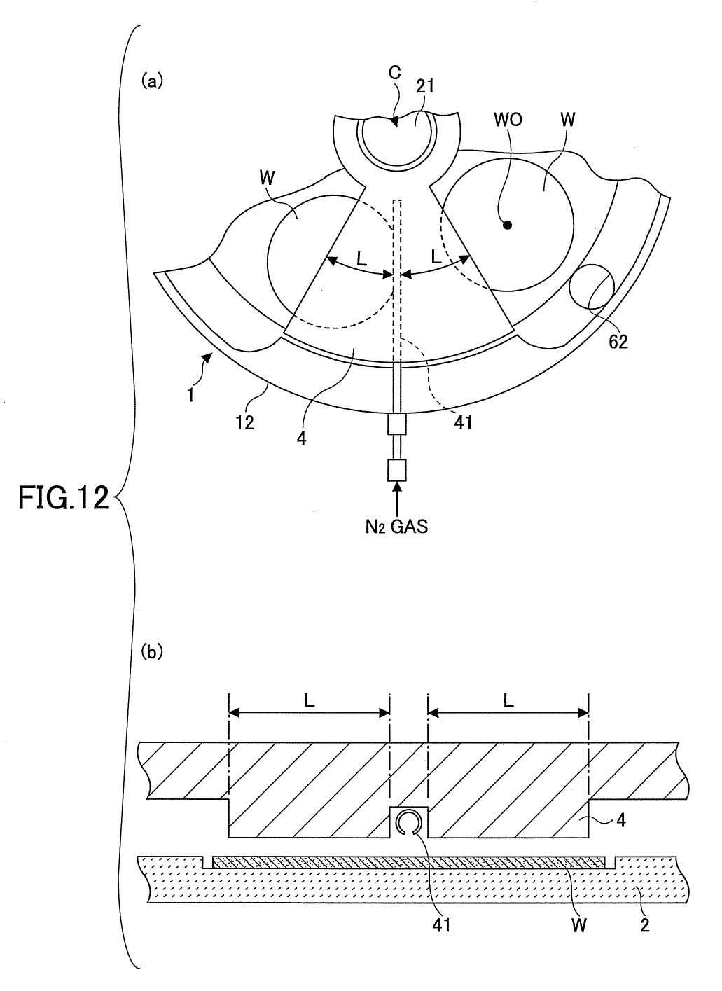

The first ceiling surface 44 that creates the thin space in both sides of the separation gas nozzle 41 (42) may preferably have a length L of about 50 mm or more, the length L being measured along an arc that corresponds to a route through which a wafer center WO passes (See FIG. 12), when the wafer W having a diameter of 300 mm is used. When the length L is set to be small, the height h of the first ceiling surface 44 from the turntable 2 needs to be small accordingly in order to efficiently impede the reaction gases from entering the thin space below the first ceiling surface 44 from both sides of the convex portion 4. In addition, when the height h of the first ceiling surface 44 from the turntable 2 is set to a certain value, the length L has to be larger in the position closer to the circumference of the turntable 2 in order to efficiently impede the reaction gases from entering the thin space below the first ceiling surface 44 because a linear speed of the turntable 2 becomes higher in the position further away from the rotation center of the turntable 2. When considered from this viewpoint, when the length L measured along the route through which the wafer center WO passes is smaller than 50 mm, the height h of the thin space needs to be significantly small. Therefore, measures to dampen vibration of the turntable 2 are required in order to prevent the turntable 2 or the wafer W from hitting the ceiling surface 52 when the turntable 2 is rotated. Furthermore, when the rotation speed of the turntable 2 is higher, the reaction gas tends to enter the space below the convex portion 4 from the upstream side of the convex portion 4. Therefore, when the length L is smaller than about 50 mm, the rotation speed of the turntable 2 needs to be reduced, which is inadvisable in terms of throughput. Therefore, the length L is preferably about 50 mm or more, while the length L smaller than about 50 mm can demonstrate the effect explained above depending on the situation. Specifically, the length L is preferably from about one-tenth of a diameter of the wafer W through about a diameter of the wafer W, more preferably, about one-sixth or more of the diameter of the wafer W. Incidentally, the convex portion 24 is omitted in Subsection (a) of FIG. 12.

Moreover, while the lower ceiling surface (first ceiling surface) 44 is provided in both sides of the separation gas nozzle 41 (42) in order to provide the thin space, the ceiling surface, which is lower than the ceiling surface 45 and as low as the ceiling surface 44 of the separation area D, may be provided for both reaction gas nozzles 31, 32 and extended to reach the ceiling surfaces 44 in other embodiments. In other words, except for portions where the separation gas nozzles 41, 42, the reaction gas nozzle 31, and the reaction gas nozzle 32 are respectively arranged (or the groove portions 43 in FIG. 4), the low ceiling surfaces 2 are provided in order to face substantially the entire upper surface of the turntable 2. From a different point of view, the ceiling surface 44 is extended to the vicinities of the first reaction gas nozzle 31 and the second reaction gas nozzle 32. Even with this, the same effect as the configuration explained above is obtained. In this case, the separation gas spreads to both sides of the separation gas nozzle 41 (42), and the reaction gases spread to both sides of the corresponding reaction gas nozzles 31, 32. The reaction gas and the separation gas flow into each other in the thin space and are evacuated through the evacuation port 61 (62).

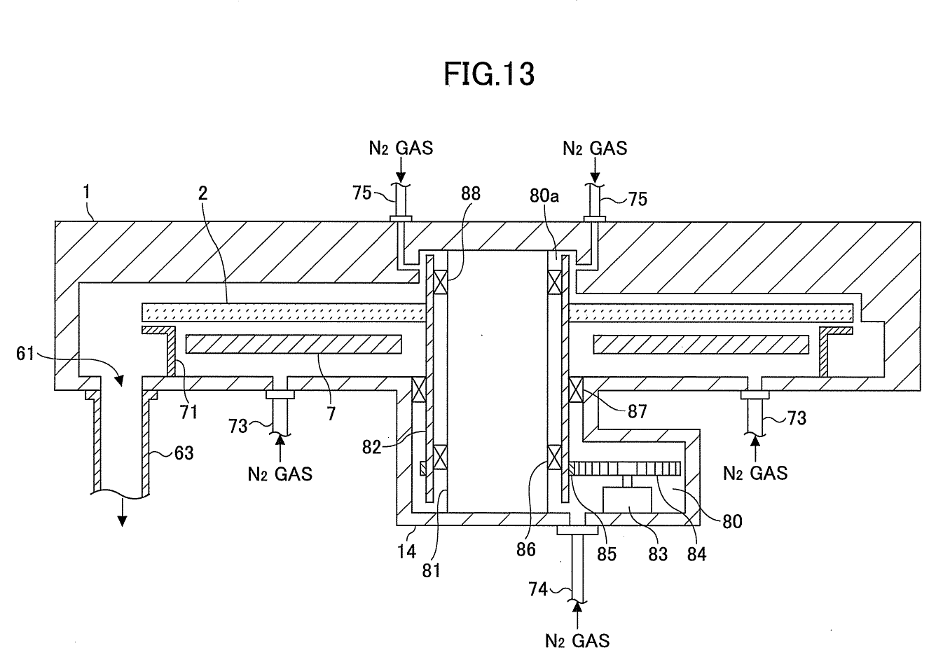

In the above embodiments, the rotational shaft 22 for rotating the turntable 2 is located in the center portion of the chamber 1. In addition, the space between the center portion 2 and the lower surface of the ceiling plate 11 is purged with the separation gas. However, the vacuum chamber 1 may be configured as shown in FIG. 13 in other embodiments. Referring to FIG. 13, the bottom portion 14 of the chamber body 12 is protruded downward in the center, so that a housing case 80 is created that houses a driving portion 83. Additionally, a center ceiling portion of the vacuum chamber 1 is dented upward, so that a center concave portion 80a is created. A pillar 81 is placed on the bottom surface of the housing case 80, and a top end portion of the pillar 81 reaches a bottom surface of the center concave portion 80a. The pillar 81 can impede the first reaction gas (BTBAS) ejected from the first reaction gas nozzle 31 and the second reaction gas (O₃) ejected from the second reaction gas nozzle 32 from being intermixed through the center portion of the vacuum chamber 1.

In addition, a rotation sleeve 82 is provided so that the rotation sleeve 82 coaxially surrounds the pillar 81. The rotation sleeve 82 is provided with the turntable 2 in such a manner that an inner circumference of the ring-shaped turntable 2 is attached on the outer surface of the rotation sleeve 82. A driving gear 84 that is driven by the driving portion 83 is provided in the housing case 80 in order to drive the rotation sleeve 82 via a gear portion 85 arranged around the outer circumferential surface of the rotation sleeve 82. Reference symbols 86, 86, and 88 are bearings. A purge gas supplying pipe 74 is connected to an opening formed in a bottom of the housing case 80, so that a purge gas is supplied into the housing case 80. In addition, purge gas supplying pipes 75 are connected to an upper portion of the vacuum chamber 1, so that a purge gas is supplied to a space between the side wall of the concave portion 80a and an upper end portion of the rotation sleeve 82. Although the two purge gas supplying pipes 75 are illustrated in FIG. 13, the number of the purge gas supplying pipes 75 may be determined so that the purge gas from the purge gas supplying pipes 75 can assuredly avoid gas mixture of the BTBAS gas and the O₃ gas in and around the space between the outer surface of the rotation sleeve 82 and the side wall of the concave portion 80a.

In the embodiment illustrated in FIG. 13, a space between the side wall of the concave portion 80a and the upper end portion of the rotation sleeve 82 corresponds to the ejection hole for ejecting the separation gas. In addition, the center area is configured with the ejection hole, the rotation sleeve 82, and the pillar 81.

Furthermore, a film deposition apparatus to which various reaction gas nozzles are applicable is not limited to a turntable type shown in FIGS. 1, 2 and the like. For example, the reaction gas nozzles explained above may be provided in a vacuum chamber that is provided with a wafer conveyor that holds and moves wafers through partitioned process areas, in the place of the turntable 2. In addition, the reaction gas nozzles may be provided in a single-wafer type film deposition apparatus, where a single wafer is placed on a stationary susceptor and a film is deposited on the wafer. Moreover, while the turntable 2 is rotated in relation to the reaction gas nozzles 31, 32, the separation gas nozzles 41, 42, the convex portions 4, and the laser beam irradiation portion 201 in the above embodiments, the reaction gas nozzles 31, 32, the separation gas nozzles 41, 42, the convex portions 4, and the laser beam irradiation portion 201 may be rotated in relation to a stationary table on which the wafers are placed. In this case, an area upstream relative to a rotation direction of the reaction gas nozzles 31, 32, the separation gas nozzles 41, 42, the convex portions 4, and the laser beam irradiation portion 201 corresponds to an upstream side of the relative rotation.

Although the invention has been described in conjunction with the foregoing specific embodiment, many alternatives, variations and modifications will be apparent to those of ordinary skill in the art. Those alternatives, variations and modifications are intended to fall within the scope of the appended claims.

What is claimed is:

1. A film deposition apparatus for depositing a film on a substrate by performing a cycle of alternately supplying at least two kinds of reaction gases that react with each other to the substrate to produce a layer of a reaction product in a vacuum chamber, the film deposition apparatus comprising:
a table that is provided in the vacuum chamber and has a substrate receiving area in which the substrate is placed;
a first reaction gas supplying portion that supplies a first reaction gas to the substrate on the table;
a second reaction gas supplying portion that supplies a second reaction gas to the substrate on the table;
a laser beam irradiation portion that is provided opposing the substrate receiving area so that the laser beam irradiation portion is capable of irradiating a laser beam to an area spanning from one edge to another edge of the substrate receiving area along a direction from an inner side to an outer side of the table;
a rotation mechanism that enables a relative rotation of the table and a combination of the first reaction gas supplying portion, the second reaction gas supplying portion, and the laser beam irradiation portion; and
a vacuum evacuation portion that evacuates an inside of the vacuum chamber,
wherein the first reaction gas supplying portion, the second reaction gas supplying portion, and the laser beam irradiation portion are arranged so that the substrate is positioned in order of a first process area where the first reaction gas is supplied, a second process area where the second reaction gas is supplied, and an irradiation area to which the laser beam is irradiated during the relative rotation.

2. The film deposition apparatus of claim 1, wherein the laser beam irradiation portion emits a laser beam having a wavelength that enables heating of the substrate, thereby heating the laser beam irradiation area.

3. The film deposition apparatus of claim 1, wherein the laser beam irradiation portion emits a laser beam having a wavelength that enables chemically altering of a reaction product of the first reaction gas and the second reaction gas.

4. The film deposition apparatus of claim 1, further comprising a separation area provided downstream relative to a direction of the relative rotation in relation to the second process area in order to separate atmospheres of the first process area and the second process area, wherein a separation gas is supplied in the separation area from a separation gas supplying portion,
wherein the irradiation area is arranged between the second process area and the separation area.

5. A film deposition method for depositing a film on a substrate by performing a cycle of alternately supplying at least two kinds of reaction gases that react with each other to the substrate to produce a layer of a reaction product in a vacuum chamber, the film deposition method comprising steps of:
placing the substrate on a table that is provided in the vacuum chamber and has a substrate receiving area in which the substrate is placed;
vacuum evacuating an inside of the vacuum chamber;
relatively rotating the table and a combination of a first reaction gas supplying portion, a second reaction gas supplying portion, and a laser beam irradiation portion;
supplying a first reaction gas from the first reaction gas supplying portion to the substrate;
supplying a second reaction gas from the second reaction gas supplying portion to the substrate; and
irradiating a laser beam to an area spanning from one edge to another edge of the substrate in the substrate receiving area along a direction from an inner side to an outer side of the table.

6. The film deposition method of claim 5, wherein the step of irradiating the laser beam includes a step of emitting a laser beam having a wavelength that enables heating of the substrate, thereby heating the laser beam irradiation area.

7. The film deposition method of claim 5, wherein the step of irradiating the laser beam includes a step of emitting a laser beam having a wavelength that enables chemically altering of a reaction product of the first reaction gas and the second reaction gas.

8. The film deposition method of claim 5, further comprising a step of supplying a separation gas from a separation gas supplying portion to a separation area provided downstream relative to a direction of the relative rotation in relation to a second process area where the second reaction gas is supplied, in order to separate atmospheres of the second process area and a first process area where the first reaction gas is supplied.

9. A storage medium storing a computer program to be used in a film deposition apparatus for depositing a film on a substrate by performing a cycle of alternately supplying at least two kinds of reaction gases that react with each other to the substrate to produce a layer of a reaction product in a vacuum chamber, the computer program includes a group of instructions that cause the film deposition apparatus to perform the film deposition method of claim 5.
